(19) United States
(12) Patent Application Publication
(10) Pub. No.: US 2026/0324502 A1
(43) Pub. Date: Oct. 15, 2026

(54) STACK PACKAGE INCLUDING SEMICONDUCTOR DIES AND ENCAPSULANT

(71) Applicant: SK hynix Inc., Icheon-si Gyeonggi-do (KR)

(72) Inventors: Kyung Beom SEO, Icheon-si Gyeonggi-do (KR); Jong Kyu MOON, Icheon-si Gyeonggi-do (KR); Jong Hyock PARK, Icheon-si Gyeonggi-do (KR)

(73) Assignee: SK hynix Inc., Icheon-si Gyeonggi-do (KR)

(21) Appl. No.: 19/464,113

(22) Filed: Jan. 29, 2026

Related U.S. Application Data
(62) Division of application No. 17/976,215, filed on Oct. 28, 2022, now abandoned.

(30) Foreign Application Priority Data
Jul. 7, 2022 (KR) 10-2022-0083583

(51) Int. Cl. H10W 90/00; H10W 20/20; H10W 46/00; H10W 74/10; H10W 74/00; H10W 90/20

(52) U.S. Cl. CPC H10W 90/00; H10W 20/20; H10W 46/00; H10W 74/111; H10W 74/141; H10W 46/301; H10W 46/603; H10W 74/00; H10W 90/297; H10W 90/722

(57) ABSTRACT

A stack package includes stacked semiconductor dies and an encapsulant. The encapsulant is formed to cover sides of the stacked semiconductor dies. A first semiconductor die of the stack package has an overhang portion that protrudes farther into the encapsulant than a second semiconductor die of the stack package.

### CROSS-REFERENCE TO RELATED APPLICATION

The present application is a divisional application of U.S. patent application no. 17/976,215, filed on Oct. 28, 2022, which claims priority under 35 U.S.C 119(a) to Korean Application No. 10-2022-0083583, filed on Jul. 7, 2022, which applications are incorporated herein by reference in their entirety.

### BACKGROUND

### 1. Technical Field

The present disclosure relates to a semiconductor package and, more particularly, to a stack package including semiconductor dies and an encapsulant.

### 2. Related Art

Integrated circuits may be integrated into a semiconductor substrate, and the semiconductor substrate may be diced to form semiconductor dies. The integrated circuit may be constructed to include a plurality of electronic components. The electronic components may include transistors, capacitors, resistors, and/or diodes. A semiconductor package may include the semiconductor dies and an encapsulant. As a large number of integrated circuits or electronic components are required to be included in the semiconductor package, a plurality of semiconductor dies may be substantially perpendicularly stacked. In order to electrically connect the stacked semiconductor dies, the semiconductor dies may include through vias. The encapsulant may be formed to cover and protect the semiconductor dies.

### SUMMARY

In accordance with an embodiment of the present disclosure is a stack package including stacked semiconductor dies including a first semiconductor die and a second semiconductor die. An encapsulant covers sides of the stacked semiconductor dies. The first semiconductor die has an overhang portion that protrudes farther into the encapsulant than the second semiconductor die.

In accordance with another embodiment of the present disclosure is a stack package including a die stack in which first semiconductor dies and second semiconductor dies are alternately stacked. An encapsulant covers sides of the die stack. The first semiconductor dies comprise overhang portions that protrude farther into the encapsulant than the second semiconductor dies.

In accordance with still another embodiment of the present disclosure is a stack package including a die stack in which first semiconductor dies and second semiconductor dies are alternately stacked. An encapsulant covers first and second sides of the die stack, which are opposite to each other. The encapsulant comprises an encapsulant-first portion that covers the first side of the die stack and an encapsulant-second portion that covers the second side of the die stack. The first semiconductor dies comprise first overhang portions that protrude farther into the encapsulant-first portion than the second semiconductor dies. The second semiconductor dies comprise second overhang portions that protrude farther into the encapsulant-second portion than the first semiconductor dies.

### BRIEF DESCRIPTION OF THE DRAWINGS

FIG. 1 is a schematic cross-sectional view illustrating a stack package according to an embodiment.

FIG. 2 is a schematic diagram illustrating an enlarged portion of the stack package shown in FIG. 1.

FIG. 3 is a schematic plan view illustrating a first semiconductor die of the stack package shown in FIG. 1.

FIG. 4 is a schematic plan view illustrating a second semiconductor die of the stack package shown in FIG. 1.

FIG. 5 is a schematic diagram illustrating another enlarged portion of the stack package shown in FIG. 1.

FIG. 6 is a schematic cross-sectional view illustrating a stack package according to another embodiment.

FIG. 7 is a schematic cross-sectional view illustrating a stack package according to another embodiment.

FIG. 8 is a schematic cross-sectional view illustrating a stack package according to another embodiment.

FIG. 9 is a schematic diagram illustrating an action that suppresses the delamination of an encapsulant in a stack package according to another embodiment.

FIGS. 10 and 11 are schematic cross-sectional views illustrating a method of dicing semiconductor dies that are included in a stack package according to an embodiment.

FIG. 12 is a block diagram illustrating an electronic system using a memory card including a stack package according to an embodiment.

FIG. 13 is a block diagram illustrating an electronic system including a stack package according to an embodiment.

### DETAILED DESCRIPTION

Terms used in the writing of an example of this application are terms selected by taking into consideration their functions in proposed embodiments. The meanings of the terms may be different depending on a user or operator’s intention or practice. The meanings of terms used herein follow defined definitions if the meanings of the terms have been specifically defined in this specification, and may be construed as having meanings commonly recognized by those skilled in the art if the meanings of the terms have not been specifically defined.

In the writing of the present disclosure, members, such as a "first" and a "second”, a “side”, a “top”, and a “bottom or lower”, are used to distinguish between members, and are not used to limit the members themselves or to mean a specific sequence of the members.

A semiconductor package may include a semiconductor die, a semiconductor substrate, or a plurality of semiconductor dies. The semiconductor package may include a die stack structure in which the semiconductor dies have been substantially perpendicularly stacked. The semiconductor dies may denote a semiconductor chip in which electronic parts and components have been integrated.

The semiconductor chip may denote a memory chip in which memory integrated circuits, such as DRAM, SRAM, a NAND flash, a NOR flash, MRAM, ReRAM, FeRAM, or PcRAM, have been integrated on a semiconductor substrate. The semiconductor chip may denote a processor, such as a logic die, an ASIC chip, an application processor (AP), a graphic processing unit (GPU), a central processing unit (CPU), or a system on chip (SoC) in which logic circuits have been integrated on a semiconductor substrate.

A semiconductor package may be applied to an information communication device such as a portable terminal, bio or healthcare-related electronic devices, or wearable electronic devices. The semiconductor package may be applied to the Internet of things (IoT).

Throughout this specification, the same reference numerals may denote the same elements. Although not indicated or described in a corresponding drawing, the same reference numerals or similar reference numerals may be described on the basis of another drawing. Furthermore, although a reference numeral is not indicated in a corresponding drawing, the reference numeral may be described on the basis of another drawing.

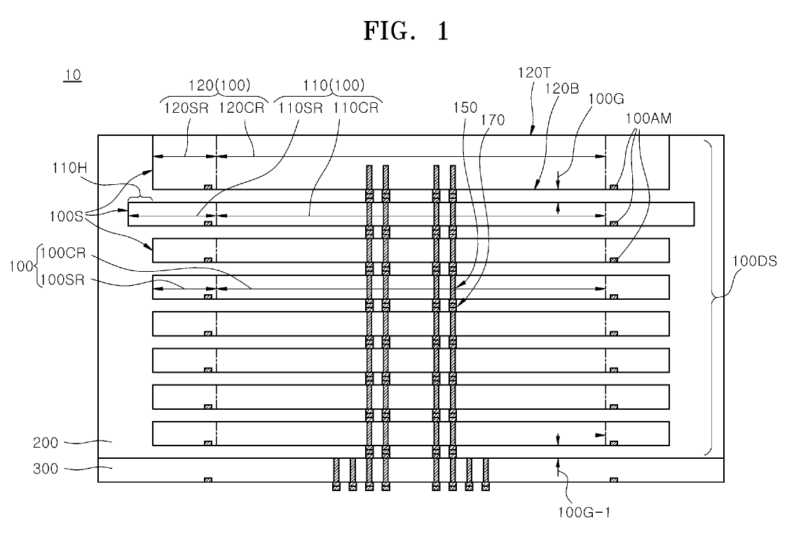

FIG. 1 is a schematic cross-sectional view illustrating a stack package 10 according to an embodiment.

Referring to FIG. 1, the stack package 10 may be constructed to include semiconductor dies 100 and an encapsulant 200. A plurality of semiconductor dies 100 may be mutually stacked. The plurality of semiconductor dies 100 may be mutually stacked in a direction that is perpendicular to the semiconductor die 100. Another semiconductor die 100 may be stacked on one semiconductor die 100. The encapsulant 200 may be formed to cover and protect some portion of the stacked semiconductor dies 100. The encapsulant 200 may be formed to cover sides 100S of the stacked semiconductor dies 100.

A first semiconductor die 110 and a second semiconductor die 120 may be any two of the stacked semiconductor dies 100. The first semiconductor die 110 that is any one of the stacked semiconductor dies 100 may include an overhang portion 110H. The overhang portion 110H of the first semiconductor die 110 may denote some portion of the first semiconductor die 110 that protrudes farther in the encapsulant 200 than the second semiconductor die 120. The second semiconductor die 120 may be disposed on the first semiconductor die 110. The overhang portion 110H of the first semiconductor die 110 may protrude farther in the encapsulant 200 than the remainder of the semiconductor dies 100 other than the first semiconductor die 110 and the second semiconductor die 120. The overhang portion 110H of the first semiconductor die 110 may have a shape that penetrates farther into the encapsulant 200 than the other semiconductor dies, and thus may play a role of suppressing the delamination of the encapsulant 200 from the sides 100S of the semiconductor dies 100 attributable to stress.

The second semiconductor die 120 may be a semiconductor die 100 that is disposed at the top tier of the stacked semiconductor dies 100. The semiconductor dies 100 may be mutually stacked to constitute a die stack 100DS. The second semiconductor die 120 may be a semiconductor die 100 that is disposed at the top tier of the die stack 100DS. The first semiconductor die 110 may be another semiconductor die 100 that has been disposed just under the second semiconductor die 120.

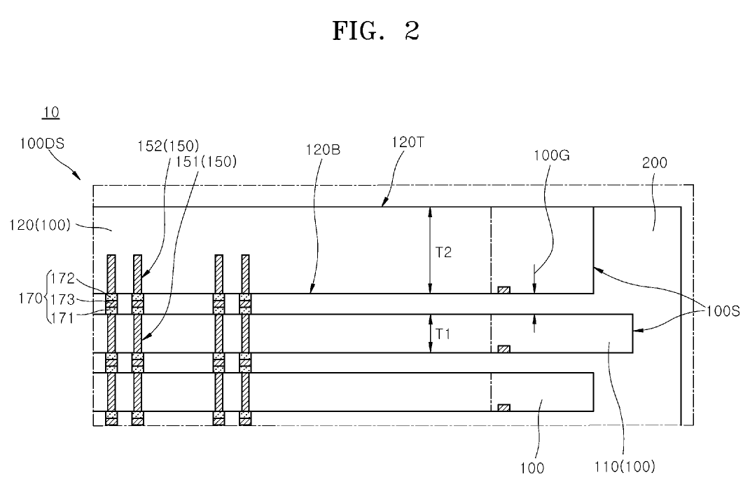

FIG. 2 is a schematic diagram illustrating an enlarged portion of the stack package 10 shown in FIG. 1.

Referring to FIG. 2, the second semiconductor die 120 may be disposed so that a top surface 120T thereof is exposed from the encapsulant 200. The top surface 120T of the second semiconductor die 120 may be a surface that is opposite to a bottom surface 120B of the second semiconductor die 120. As the second semiconductor die 120 is disposed on the first semiconductor die 110, the bottom surface 120B of the second semiconductor die 120 may be a surface that faces the first semiconductor die 110. As the top surface 120T of the second semiconductor die 120 is exposed from the encapsulant 200, heat that is generated when the semiconductor dies 100 operate can be discharged to the outside through the top surface 120T of the second semiconductor die 120 without interruption from the encapsulant 200. A structure in which the top surface 120T of the second semiconductor die 120 is exposed from the encapsulant 200 without being covered by the encapsulant 200 can improve the discharge of heat of the stack package 10.

In the second semiconductor die 120, the top surface 120T of the second semiconductor die 120 may be exposed to an external environment because the top surface 120T is exposed from the encapsulant 200 without being covered by the encapsulant 200. As the top surface 120T of the second semiconductor die 120 may be directly exposed to an external impact, the second semiconductor die 120 may be more relatively vulnerable to damage by the external impact than the underlying first semiconductor die 110. In order to suppress the second semiconductor die 120 from being damaged, the second semiconductor die 120 may have a thickness T2 greater than a thickness T1 of the first semiconductor die 110.

Referring back to FIGS. 1 and 2, the encapsulant 200 may be extended to cover the sides 100S of the stacked semiconductor dies 100 and to fill gaps 100G between the stacked semiconductor dies 100. The encapsulant 200 may be formed to include an encapsulation material, such as an epoxy mold compound (EMC). The encapsulant 200 may be molded in the form of a molded underfill (MUF) that fills the gaps 100G between the stacked semiconductor dies 100 while covering the sides 100S of the stacked semiconductor dies 100. As the encapsulant 200 is extended to fill the gaps 100G between the semiconductor dies 100 that have been stacked, adhesive layers that bond the semiconductor dies 100 between the semiconductor dies 100 may be omitted.

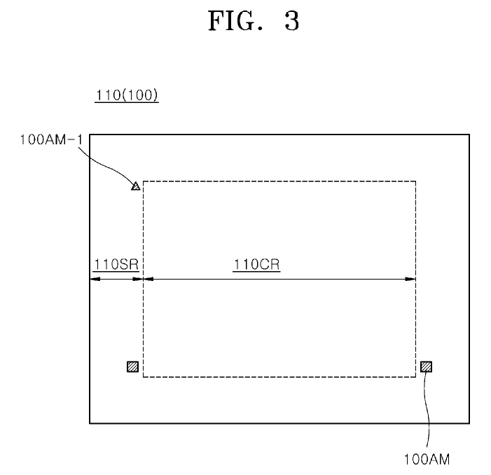

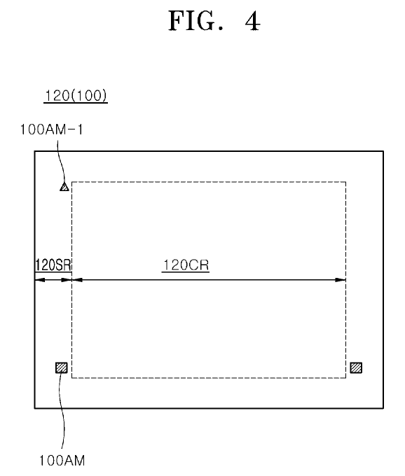

FIG. 3 is a schematic plan view illustrating the first semiconductor die 110 shown in FIG. 1. FIG. 4 is a schematic plan view illustrating the second semiconductor die 120 in FIG. 1.

Referring to FIG. 3, the first semiconductor die 110 may include a first chip region 110CR and a first scribe lane region 110SR. Referring to FIG. 4, the second semiconductor die 120 may include a second chip region 120CR and a second scribe lane region 120SR. The first chip region 110CR of the first semiconductor die 110 may have substantially the same plane shape and the same width as the second chip region 120CR of the second semiconductor die 120. The second scribe lane region 120SR of the second semiconductor die 120 may have a smaller width than the first scribe lane region 110SR of the first semiconductor die 110.

Referring to FIG. 1, the second semiconductor die 120 may be disposed on the first semiconductor die 110 so that the second chip region 120CR substantially fully overlaps the first chip region 110CR. Referring to FIGS. 1, 3, and 4, the first and second semiconductor dies 110 and 120 may further include alignment marks 100AM and 100AM-1 that indicate locations at which the first and second semiconductor dies 110 and 120 are stacked so that the second chip region 120CR of the second semiconductor die 120 substantially fully overlaps the first chip region 110CR of the first semiconductor die 110 when the first and second semiconductor dies 110 and 120 are stacked.

The alignment marks 100AM and 100AM-1 may be disposed outside edges of the first and second chip regions 110CR and 120CR of the first and second semiconductor dies 110 and 120. The alignment marks 100AM and 100AM-1 may be disposed at portions that are adjacent to the edges of the first and second chip regions 110CR and 120CR of the first and second scribe lane regions 110SR and 120SR of the first and second semiconductor dies 110 and 120.

The alignment marks 100AM and 100AM-1 may include a first alignment mark 100AM and a second alignment mark 100AM-1 that diagonally face each other. The first alignment mark 100AM and the second alignment mark 100AM-1 may have different shapes. The first alignment mark 100AM may be formed as a pattern that has a rectangular plane shape when viewed on a plane. The second alignment mark 100AM-1 may be formed as a pattern that has a triangular plane shape when viewed on a plane. The first alignment mark 100AM and the second alignment mark 100AM-1 are not limited to the patterns having the rectangular plane shape or the triangular plane shape.

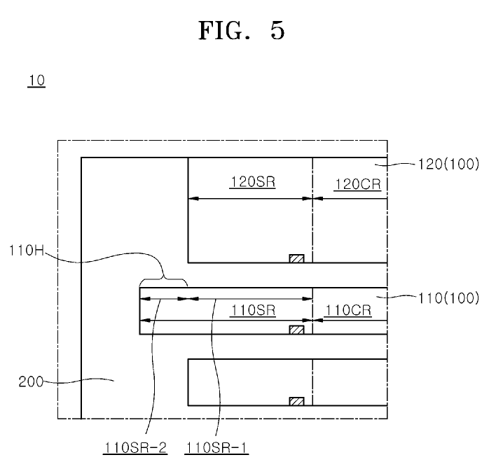

FIG. 5 is a schematic diagram illustrating another enlarged portion of the stack package 10 shown in FIG. 1.

Referring to FIG. 5, the second semiconductor die 120 may be aligned with the first semiconductor die 110 by using the alignment marks 100AM so that the second chip region 120CR of the second semiconductor die 120 substantially fully overlaps the first chip region 110CR of the first semiconductor die 110. Accordingly, the second scribe lane region 120SR of the second semiconductor die 120 may overlap some portion 110SR-1 of the first scribe lane region 110SR of the first semiconductor die 110. The remaining portion 110SR-2 of the first scribe lane region 110SR of the first semiconductor die 110 may become the overhang portion 110H that further protrudes to the outside of the second scribe lane region 120SR of the second semiconductor die 120. When the second chip region 120CR of the second semiconductor die 120 overlaps the first chip region 110CR of the first semiconductor die 110, the portion 110SR-2 of the first scribe lane region 110SR of the first semiconductor die 110 may construct the overhang portion 110H because the first scribe lane region 110SR of the first semiconductor die 110 has a greater width than the second scribe lane region 120SR of the second semiconductor die 120.

Referring back to FIG. 1, each of the semiconductor dies 100 may include a chip region 100CR and a scribe lane region 100SR. The first and second semiconductor dies 110 and 120 may be any two of the semiconductor dies 100. The first and second chip regions 110CR and 120CR of the first and second semiconductor dies 110 and 120 may have substantially the same shape and width as the chip region 100CR of the semiconductor die 100. The second scribe lane region 120SR of the second semiconductor die 120 may have substantially the same shape and width as the scribe lane region 100SR of the semiconductor die 100. In an embodiment, the second scribe lane region 120SR of the second semiconductor die 120 may have a smaller width than the scribe lane region 100SR of the semiconductor die 100. The first scribe lane region 110SR of the first semiconductor die 110 may have a greater width than the scribe lane region 100SR of the semiconductor die 100.

The first and second semiconductor dies 110 and 120, and the semiconductor dies 100 may include a semiconductor substrate and integrated circuit devices that are integrated on the semiconductor substrate. The semiconductor substrate may include a semiconductor material, such as silicon (Si) or germanium (Ge). The semiconductor substrate may include a compound semiconductor material, such as silicon carbide (SiC), gallium arsenide (GaAs), indium arsenide (InAs), or indium phosphorous (InP).

The chip region 100CR of the semiconductor die 100 may be a region in which the integrated circuit devices are disposed. First and second chip regions 110CR and 120CR of the first and second semiconductor dies 110 and 120 may be regions in which integrated circuit devices are disposed. The scribe lane region 100SR of the semiconductor die 100 and the first and second scribe lane regions 110SR and 120SR of the first and second semiconductor dies 110 and 120 may be regions that fill the chip regions 100CR, 110CR, and 120CR. The chip regions 100CR, 110CR, and 120CR of the semiconductor dies 100, 110, and 120 may be regions in which pattern density is relatively high. The scribe lane regions 100SR, 110SR, and 120SR of the semiconductor dies 100, 110, and 120 may be regions in which pattern density is relatively low.

The integrated circuit devices may include semiconductor devices or memory devices. The integrated circuit devices may be volatile memory devices including memory such as dynamic random access memory (DRAM). The integrated circuit devices may be nonvolatile memory devices including memory such as flash memory.

Although not illustrated, electronic components that constitute the integrated circuit devices may be formed in the chip regions 100CR, 110CR, and 120CR of the semiconductor dies 100, 110, and 120. Although not illustrated, gate structures that constitute transistor structures may be formed in the chip regions 100CR, 110CR, and 120CR of the semiconductor dies 100, 110, and 120. Although not illustrated, memory devices which include a gate dielectric layer, a plurality of word lines, and a plurality of bit lines may be formed in the chip regions 100CR, 110CR, and 120CR of the semiconductor dies 100, 110, and 120.

Referring back to FIG. 1, the stack package 10 may further include a base die 300. The semiconductor dies 100 may be disposed on the base die 300. The encapsulant 200 may be further extended to fill a gap 100G-1 between the semiconductor dies 100 and the base die 300. The base die 300 may have a greater width than each of the semiconductor dies 100 in a way to support both the die stack 100DS of the semiconductor dies 100 and the encapsulant 200.

A structure in which the die stack 100DS has been stacked on the base die 300 may construct a high bandwidth memory (HBM) device. The semiconductor dies 100 that have been mutually stacked to constitute the die stack 100DS may include memory devices. The base die 300 may include logic circuits for controlling operations of the memory devices integrated on the semiconductor dies 100 and controlling the transmission of a signal to the memory devices. The semiconductor dies 100 may be connected to external another module or electronic parts electrically or signally through the base die 300.

FIG. 1 presents a form in which the base die 300 supports the semiconductor dies 100 and the encapsulant 200, but a package substrate (not illustrated) may support the semiconductor dies 100 and the encapsulant 200. The package substrate may have a printed circuit board (PCB) form. Alternatively, an interconnection structure which includes redistributed layers (RDLs) and dielectric layers may be disposed under the semiconductor dies 100 and the encapsulant 200, so that the stack package 10 may be constructed in the form of a fan-out package. Alternatively, an interposer may be disposed under the semiconductor dies 100 and the encapsulant 200.

Referring back to FIG. 1, the semiconductor dies 100 may include through vias 150 that are disposed in the chip regions 100CR. The through vias 150 may include a conductive material or a metal material. The through via 150 may have a through silicon via (TSV) shape. The through vias 150 may be extended to penetrate the semiconductor dies 100. The through vias 150 may be electrically connected to the integrated circuits that are integrated into the semiconductor dies 100. The through vias 150 and other through vias 150 on the upper side (or the lower side) thereof may be mutually electrically connected by conductive connectors 170. The semiconductor dies 100 may be mutually electrically connected by the through vias 150 and the conductive connectors 170. The through vias 150 may be further disposed in the base dies 300. The semiconductor dies 100 may be electrically connected to the base die 300 by the through vias 150 and the conductive connectors 170.

Referring back to FIG. 2, the first and second semiconductor dies 110 and 120 may include the through vias 150 that are disposed in the first and second chip regions 110CR and 120CR. First through vias 151 may be disposed to substantially penetrate the first chip region 110CR of the first semiconductor die 110. Second through vias 152 may be disposed to extend from the second chip region 120CR of the second semiconductor die 120 to the second semiconductor die 120 and penetrate thereto. The second through vias 152 may not be exposed to the top surface 120T because the second through vias 152 are not extended up to the top surface 120T of the second semiconductor die 120. The second through vias 152 may be disposed at locations corresponding to the first through vias 151, respectively.

The second through vias 152 of the second semiconductor die 120 may be connected to the first through vias 151 of the first semiconductor die 110 by the conductive connectors 170, respectively. The conductive connectors 170 may include a first connector 171, a conductive adhesive layer 173, and a second connector 172. The first connector 171 may include a conductive pattern that is connected to the first through via 151, for example, a conductive bump. The second connector 172 may include a conductive pattern that is connected to the second through via 152, for example, a conductive bump. The conductive adhesive layer 173 may include a solder layer. It is exemplified that the second through vias 152 are connected to the first through vias 151 by the conductive connectors 170, but the present disclosure is not limited thereto. The second through vias 152 may be connected to the first through vias 151 by various connection structures.

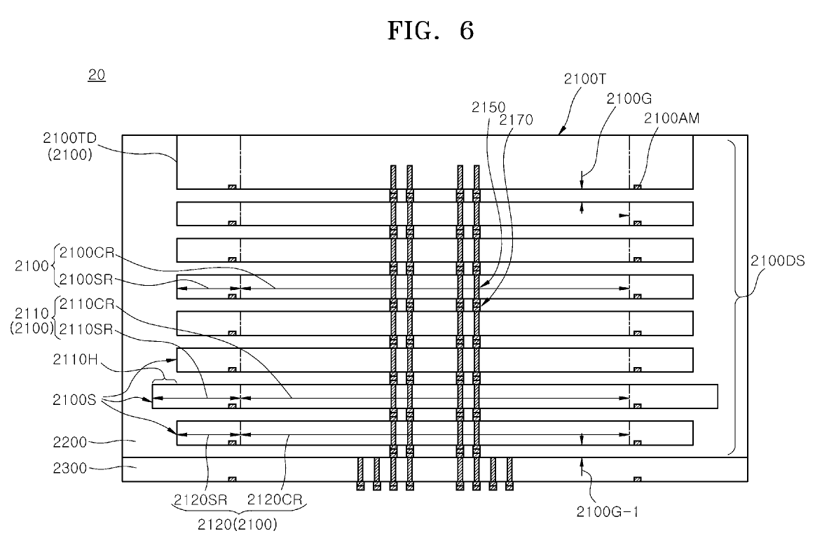

FIG. 6 is a schematic cross-sectional view illustrating a stack package 20 according to another embodiment.

Referring to FIG. 6, the stack package 20 may be constructed to include semiconductor dies 2100 and an encapsulant 2200. Each of the semiconductor dies 2100 may include a chip region 2100CR and a scribe lane region 2100SR. The plurality of semiconductor dies 2100 may be mutually stacked. The semiconductor dies 2100 may be perpendicularly stacked to constitute a die stack 2100DS. A top tier semiconductor die 2100TD that is disposed at the top tier of the die stack 2100DS, among the semiconductor dies 2100, may have a relatively greater thickness than each of other semiconductor dies 2100.

The encapsulant 2200 may be formed to cover sides 2100S of the stacked semiconductor dies 2100. The encapsulant 2200 may be formed in a shape that exposes a top surface 2100T of the top tier semiconductor die 2100TD while covering the side of the die stack 2100DS. The encapsulant 2200 may be molded in the form of an MUF that fill gaps 2100G between the stacked semiconductor dies 2100. When mutually stacked, the semiconductor dies 2100 may include alignment marks 2100AM that indicate locations at which the semiconductor dies 2100 are stacked.

The stack package 20 may further include a base die 2300. The semiconductor dies 2100 may be disposed on the base die 2300. The encapsulant 2200 may be further extended to fill a gap 2100G-1 between the semiconductor dies 2100 and the base die 2300. The base die 2300 may have a greater width than each of the semiconductor dies 2100 in a way to support both the die stack 2100DS of the semiconductor dies 2100 and the encapsulant 2200. A structure in which the die stack 2100DS has been stacked on the base die 2300 may constitute an HBM device.

A first semiconductor die 2110 and a second semiconductor die 2120 may be any two of the stacked semiconductor dies 100. The first semiconductor die 2110 may be disposed on the second semiconductor die 2120. The second semiconductor die 2120 may be disposed between the first semiconductor die 2110 and the base die 2300. The first semiconductor die 2110 may include a first chip region 2110CR and a first scribe lane region 2110SR. The second semiconductor die 2120 may include a second chip region 2120CR and a second scribe lane region 2120SR. The first semiconductor die 2110 may be stacked on the second semiconductor die 2120 so that the first chip region 2110CR of the first semiconductor die 2110 overlaps the second chip region 2120CR of the second semiconductor die 2120 by the indication of the alignment marks 2100AM.

The first semiconductor die 2110 may include an overhang portion 2110H. The overhang portion 2110H of the first semiconductor die 2110 may denote some portion of the first semiconductor die 2110 that protrudes farther into the encapsulant 2200 than the second semiconductor die 2120. The overhang portion 2110H of the semiconductor die 2110 may protrude more into the encapsulant 2200 than the remainder of the semiconductor dies 2100. The overhang portion 2100H of the first semiconductor die 2100 may play a role of suppressing the delamination of the encapsulant 2200 from the sides 2100S of the semiconductor die 2100 attributable to stress because the overhang portion 2100H has a shape that is further penetrated into the encapsulant 2200.

The semiconductor dies 2100 and the base die 2300 may include through vias 2150 for an electrical connection. The through vias 2150 and other through vias 2150 on the upper side (or the lower side) thereof may be mutually electrically connected by conductive connectors 2170.

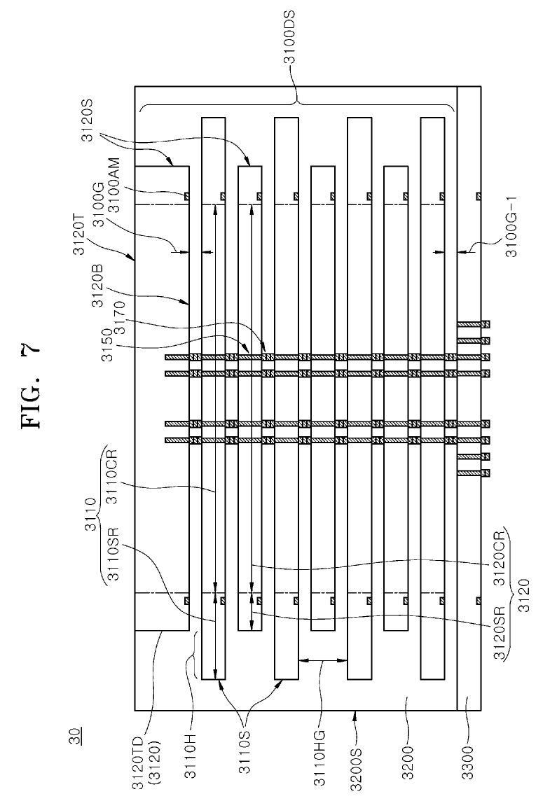

FIG. 7 is a schematic cross-sectional view illustrating a stack package 30 according to another embodiment.

Referring to FIG. 7, the stack package 30 may include a die stack 3100DS in which first semiconductor dies 3110 and second semiconductor dies 3120 have been alternately stacked. One second semiconductor die 3120 may be stacked on one first semiconductor die 3110. A form in which the second semiconductor die 3120 has been stacked on the first semiconductor die 3110 may be repeatedly further stacked on the second semiconductor die 3120.

The stack package 30 may further include an encapsulant 3200 that covers sides 3110S and 3120S of the die stack 3100DS. The encapsulant 3200 may be extended to cover first sides 3110S of the first semiconductor dies 3110 and cover second sides 3120S of the second semiconductor dies 3120. The encapsulant 3200 may be extended to fill a gap 3100G between the first semiconductor die 3110 and the second semiconductor die 3120. The encapsulant 3200 may be molded in the form of an MUF. The encapsulant 3200 may be formed to include an encapsulation material, such as an EMC.

The first semiconductor dies 3110 may include overhang portions 3110H that protrude farther into the encapsulant 3200 than the second semiconductor dies 3120, respectively. As the first semiconductor dies 3110 and the second semiconductor dies 3120 are alternatively stacked, the first sides 3110S of the first semiconductor dies 3110 may be disposed at locations different from the locations of the second sides 3120S of the second semiconductor dies 3120. The second sides 3120S of the second semiconductor dies 3120 may be disposed at locations that are more retreated from a lateral surface 3200S of the encapsulant 3200 than the first sides 3110S of the first semiconductor dies 3110.

As the first semiconductor dies 3110 and the second semiconductor dies 3120 have been alternatively stacked, a shape in which the overhang portions 3110H have repeatedly protruded toward the encapsulant 3200 may be formed. The encapsulant 3200 may be extended to fill gaps 3110HG between the overhang portions 3110H. As the overhang portions 3100H of the first semiconductor dies 3110 have the same shape as spikes that have been penetrated into the encapsulant 3200, the overhang portions 3100H may play a role of suppressing the delamination of the encapsulant 3200 from the first and second semiconductor dies 3110 and 3120 or from the first and second sides 3110S and 3120S of the first and second semiconductor dies 3110 and 3120.

One of the second semiconductor dies 3120 may be disposed at the top tier of the die stack 3100DS. A top tier-second semiconductor die 3120TD that has been disposed at the top tier of the die stack 3100DS may have a relatively greater thickness than each of other second semiconductor dies 3120 that have been disposed under the top tier-second semiconductor die 3120TD. The top tier-second semiconductor die 3120TD may have a relatively greater thickness than each of the first semiconductor dies 3110 that have been disposed under the top tier-second semiconductor die 3120TD.

The encapsulant 3200 may be formed in a shape that exposes the top surface 3120T of the top tier-second semiconductor die 3120TD while covering the sides 3110S and 3120S of the die stack 3100DS. The top surface 3120T of the top tier-second semiconductor die 3120TD may be a surface that is opposite to a bottom surface 3120B thereof. As the top tier-second semiconductor die 3120TD is disposed on the first semiconductor die 3110, the bottom surface 3120B of the top tier-second semiconductor die 3120TD may be a surface that faces the first semiconductor die 3110.

The stack package 30 may further include a base die 3300. The first and second semiconductor dies 3110 and 3120 may be disposed on the base die 3300. The die stack 3100DS may be disposed on the base die 3300. The encapsulant 3200 may be further extended to fill a gap 3100G-1 between the die stack 3100DS and the base die 3300. The base die 3300 may have a greater width than each of the first and second semiconductor dies 3110 and 3120 in a way to support both the die stack 3100DS of the first and second semiconductor dies 3110 and 3120 and the encapsulant 3200. A structure in which the die stack 3100DS have been stacked on the base die 3300 may constitute an HBM device.

The first semiconductor die 3110 may include a first chip region 3110CR and first scribe lane regions 3110SR. The first chip region 3110CR may be disposed between the first scribe lane regions 3110SR. The first scribe lane regions 3110SR may have the same width. The second semiconductor die 3120 may include a second chip region 3120CR and second scribe lane regions 3120SR. The second chip region 3120CR may be disposed between the second scribe lane regions 3120SR.

The first and second semiconductor dies 3110 and 3120 may further include alignment marks 3100AM. The alignment marks 3100AM may be disposed in the first and second scribe lane regions 3110SR and 3120SR of the first semiconductor dies 3110 and the second semiconductor dies 3120. The first and second semiconductor dies 3110 and 3120 may be mutually stacked so that the second chip region 3120CR of the second semiconductor die 3120 overlaps the first chip region 3110CR of the first semiconductor die 3110. The alignment marks 3100AM may indicate locations at which the first and second semiconductor dies 3110 and 3120 are stacked. The alignment marks 3100AM may also be disposed in the base die 3300, and may indicate a location at which the die stack 3100DS will be disposed.

The first chip region 3110CR of the first semiconductor die 3110 may have substantially the same plane shape and the same width as the second chip region 3120CR of the second semiconductor die 3120. Each of the second scribe lane regions 3120SR of the second semiconductor die 3120 may have a smaller width than the first scribe lane region 3110SR of the first semiconductor die 3110.

As the second chip region 3120CR of the second semiconductor die 3120 overlaps the first chip region 3110CR of the first semiconductor die 3110, the second scribe lane regions 3120SR of the second semiconductor die 3120 may overlap some portions of the first scribe lane regions 3110SR of the first semiconductor die 3110, respectively. The remaining other some portions of the first scribe lane regions 3110SR of the first semiconductor die 3110 may become the overhang portions 3110H that further protrude to the outside of the second scribe lane regions 3120SR of the second semiconductor die 3120. As each of the first scribe lane regions 3110SR of the first semiconductor die 3110 has a greater width than each of the second scribe lane regions 3120SR of the second semiconductor die 3120, the second chip region 3120CR of the second semiconductor die 3120 overlaps the first chip region 3110CR of the first semiconductor die 3110, so that other some portions of the first scribe lane regions 3110SR of the first semiconductor die 3110 may constitute the overhang portions 3110H.

The first and second semiconductor dies 3110 and 3120 may include through vias 3150 for an electrical connection in the first and second chip regions 3110CR, 3120CR. The base die 3300 may also further include through vias 3150 for an electrical connection. The through vias 3150 and other through vias 3150 on the upper side (or the lower side) thereof may be mutually electrically connected by conductive connectors 3170.

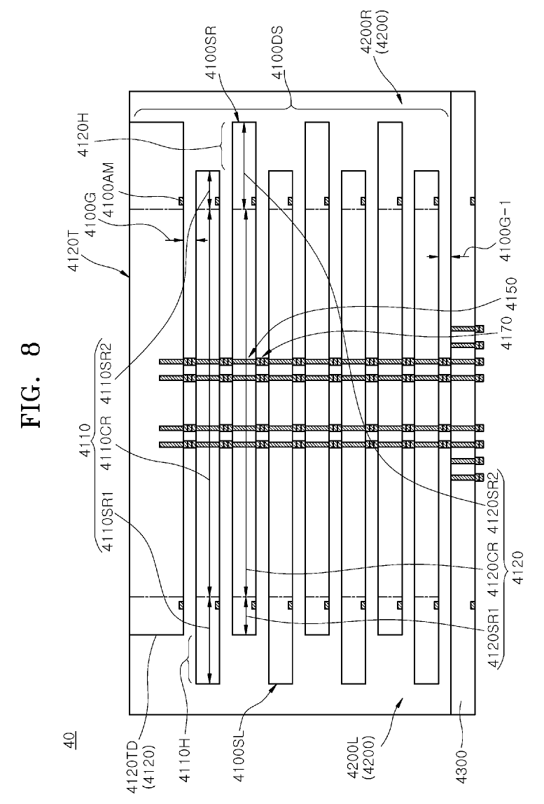

FIG. 8 is a schematic cross-sectional view illustrating a stack package 40 according to another embodiment.

Referring to FIG. 8, the stack package 40 may include a die stack 4100DS in which first semiconductor dies 4110 and second semiconductor dies 4120 have been alternately stacked. One first semiconductor die 4110 may be stacked on one second semiconductor die 4120. Alternatively, one first semiconductor die 4110 may be stacked under one second semiconductor die 4120. A form in which the first semiconductor die 4110 and the second semiconductor die 4120 have been stacked may be repeatedly further stacked.

The stack package 40 may further include an encapsulant 4200 that covers first and second sides 4100SL and 4100SR of the die stack 4100DS. The first and second sides 4100SL and 4100SR of the die stack 4100DS may be two sides that face each other or are opposite to each other. The encapsulant 4200 may include an encapsulant-first portion 4200L that covers the first side 4100SL of the die stack 4100DS. The first side 4100SL of the die stack 4100DS may include sides of the first and second semiconductor dies 4110 and 4120, which are covered by the encapsulant-first portion 4200L. The encapsulant 4200 may include an encapsulant-second portion 4200R that covers the second side 4100SR of the die stack 4100DS. The second side 4100SR of the die stack 4100DS may include other sides of the first and second semiconductor dies 4110 and 4120, which are covered by the encapsulant-second portion 4200R. The encapsulant 4200 may be extended to fill a gap 4100G between the first semiconductor die 4100 and the second semiconductor die 4120. The encapsulant 4200 may be molded in the form of an MUF. The encapsulant 4200 may be formed to include an encapsulation material, such as an EMC.

The first semiconductor dies 4110 may include first overhang portions 4110H that protrude farther into the encapsulant-first portion 4200L than the second semiconductor dies 4120, respectively. The second semiconductor dies 4120 may include second overhang portions 4120H that protrude farther into the encapsulant-second portion 4200R than the first semiconductor dies 4110, respectively. The first overhang portions 4110H of the first semiconductor dies 4110 may protrude in a direction that is opposite to the second overhang portions 4120H of the second semiconductor dies 4120.

One of the second semiconductor dies 4120 may be disposed at the top tier of the die stack 4100DS. A top tier-second semiconductor die 4120TD that is disposed at the top tier of the die stack 4100DS may have a relatively greater thickness than each of other second semiconductor dies 4120 that are disposed under the top tier-second semiconductor die 4120TD. The top tier-second semiconductor die 4120TD may have a relatively greater thickness than each of the first semiconductor dies 4110 that are disposed under the top tier-second semiconductor die 4120TD.

The encapsulant 4200 may be formed in a shape that exposes a top surface 4120T of the top tier-second semiconductor die 4120TD while covering the first and second sides 4100SL and 4100SR of the die stack 4100DS.

The stack package 40 may further include a base die 4300. The first and second semiconductor dies 4110 and 4120 may be disposed on the base die 4300. The die stack 4100DS may be disposed on the base die 4300. The encapsulant 4200 may be further extended to fill a gap 4100G-1 between the die stack 4100DS and the base die 4300. The base die 4300 may have a greater width than each of the first and second semiconductor dies 4110 and 4120 in a way to support both the die stack 4100DS of the first and second semiconductor dies 4110 and 4120 and the encapsulant 4200. A structure in which the die stack 4100DS has been stacked on the base die 4300 may constitute an HBM device.

The first semiconductor die 4110 may include a first chip region 4110CR and first and third scribe lane regions 4110SR1 and 4110SR2. The first chip region 4110CR may be disposed between the first scribe lane region 4110SR1 and the third scribe lane region 4110SR2. The first and third scribe lane regions 4110SR1 and 4110SR2 may have different widths. The third scribe lane region 4110SR2 may have a smaller width than the first scribe lane region 4110SR1.

The second semiconductor die 4120 may include a second chip region 4120CR and second and fourth scribe lane regions 4120SR1 and 4120SR2. The second chip region 4120CRmay be disposed between the second scribe lane region 4120SR1 and the fourth scribe lane region 4120SR2. The second and fourth scribe lane regions 4120SR1 and 4120SR2 may have different widths. The fourth scribe lane region 4120SR2 may have a smaller width than the second scribe lane region 4120SR1.

The first and second semiconductor dies 4110 and 4120 may further include alignment marks 4100AM. The alignment marks 4100AM may be disposed in the first and second scribe lane regions 4110SR1 and 4120SR1 of the first semiconductor dies 4110 and the second semiconductor dies 4120. The alignment marks 4100AM may be further disposed in the third and fourth scribe lane regions 4110SR2 and 4120SR2 of the first semiconductor dies 4110 and the second semiconductor dies 4120.

The first and second semiconductor dies 4110 and 4120 may be mutually stacked so that the second chip region 4120CR of the second semiconductor die 4120 overlaps the first chip region 4110CR of the first semiconductor die 4110. The alignment marks 4100AM may indicate locations at which the first and second semiconductor dies 4110 and 4120 are stacked. The alignment marks 4100AM may also be disposed in the base die 4300, and may indicate locations at which the alignment marks 4100AM will be disposed in the die stack 4100DS.

The first chip region 4110CR of the first semiconductor die 4110 may have substantially the same plane shape and the same width as the second chip region 4120CR of the second semiconductor die 4120. The second scribe lane region 4120SR1 of the second semiconductor die 4120 may have a smaller width than the first scribe lane region 4110SR1 of the first semiconductor die 4110. The third scribe lane region 4110SR2 of the first semiconductor die 4110 may have a smaller width than the fourth scribe lane region 4120SR2 of the second semiconductor die 4120.

As the second chip region 4120CR of the second semiconductor die 4120 overlaps the first chip region 4110CR of the first semiconductor die 4110, the second scribe lane region 4120SR1 of the second semiconductor die 4120 may overlap some portion of the first scribe lane region 4110SR1 of the first semiconductor die 4110. The remaining other some portion of the first scribe lane region 4110SR1 of the first semiconductor die 4110 may become the first overhang portion 4110H that further protrudes to the outside of the second scribe lane region 4120SR1 of the second semiconductor die 4120.

As the first scribe lane region 4110SR1 of the first semiconductor die 4110 has a greater width than the second scribe lane region 4120SR1 of the second semiconductor die 4120, the second chip region 4120CR of the second semiconductor die 4120 overlaps the first chip region 4110CR of the first semiconductor die 4110, so that other some portion of the first scribe lane region 4110SR1 of the first semiconductor die 4110 may constitute the first overhang portion 4110H.

As the first chip region 4110CR of the first semiconductor die 4110 overlaps the second chip region 4120CR of the second semiconductor die 4120, the third scribe lane region 4110SR2 of the first semiconductor die 4110 may overlap some portion of the fourth scribe lane region 4120SR2 of the second semiconductor die 4120. The remaining other some portion of the fourth scribe lane region 4120SR2 of the second semiconductor die 4120 may become the second overhang portion 4120H that further protrudes to the outside of the third scribe lane region 4110SR2 of the first semiconductor die 4110.

As the fourth scribe lane region 4120SR2 of the second semiconductor die 4120 has a greater width than the third scribe lane region 4110SR2 of the first semiconductor die 4110, the first chip region 4110CR of the first semiconductor die 4110 overlaps the second chip region 4120CR of the second semiconductor die 4120, so that other some portion of the fourth scribe lane region 4120SR2 of the second semiconductor die 4120 may constitute the second overhang portion 4120H.

In the die stack 4100DS, the first and second overhang portions 4110H and 4120H of the first and second semiconductor dies 4110 and 4120 may play a role of suppressing the delamination of the encapsulant 4200 from the die stack 4100DS. Each of the first overhang portions 4110H of the first semiconductor dies 4110 has a shape, such as a spike, that penetrates into the encapsulant-first portion 4200L. Accordingly, the delamination of the encapsulant-first portion 4200L from the first and second semiconductor dies 4110 and 4120 or from the first side 4100SL of the die stack 4100DS can be suppressed. Each of the second overhang portions 4200H of the second semiconductor dies 4120 has a shape, such as a spike, that penetrates into the encapsulant-second portion 4200R. Accordingly, the delamination of the encapsulant-second portion 4200R from the first and second semiconductor dies 4110 and 4120 or from the second side 4100SR of the die stack 4100DS can be suppressed.

The first and second semiconductor dies 4110 and 4120 may include through vias 4150 for an electrical connection in the first and second chip regions 4110CR and 4120CR. The base die 4300 may also further include through vias 4150 for an electrical connection. The through vias 4150 and other through vias 4150 on the upper side or lower side thereof may be mutually electrically connected by conductive connectors 4170.

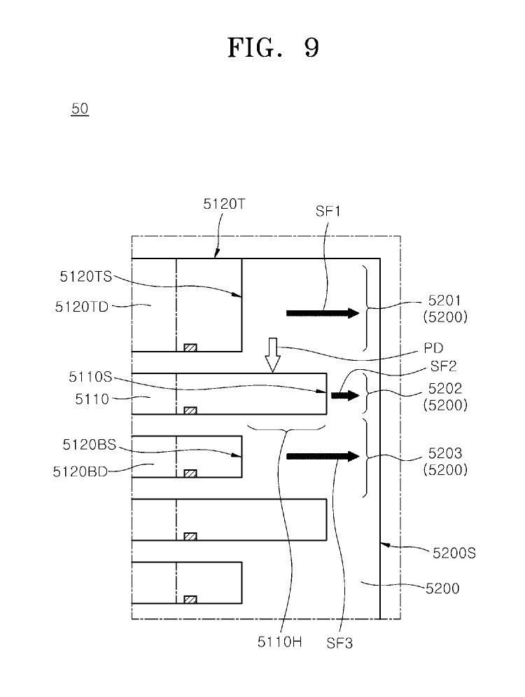

FIG. 9 is a schematic diagram illustrating an action that suppresses the delamination of an encapsulant 5200 in a stack package 50 according to another embodiment.

Referring to FIG. 9, the stack package 50 may include a first semiconductor die 5110, an upper-side second semiconductor die 5120TD, and a lower-side second semiconductor die 5120BD. The upper-side second semiconductor die 5120TD may be stacked over the first semiconductor die 5110, and the lower-side second semiconductor die 5120BD may be disposed under the first semiconductor die 5110. The encapsulant 5200 may be formed to cover sides of a die stack of the first semiconductor die 5110, the upper-side second semiconductor die 5120TD, and the lower-side second semiconductor die 5120BD. The encapsulant 5200 may be formed to expose a top surface 5120T of the upper-side second semiconductor die 5120TD. The first semiconductor die 5110 may include an overhang portion 5110H.

A shrinkage force may occur in the encapsulant 5200 during a process of forming the encapsulant 5200. In a process of molding the encapsulant 5200, a shrinkage force may occur within the encapsulant 5200 as the encapsulant 5200 is hardened. The shrinkage force may act as a force that delaminates the encapsulant 5200 from the semiconductor dies 5110, 5120TD, and 5120BD. Such a shrinkage force may be increased in proportion to the volume of the encapsulant 5200.

The encapsulant 5200 may include an encapsulant-first sub-portion 5201, an encapsulant-second sub-portion 5202, and an encapsulant-third sub-portion 5203. The encapsulant-first sub-portion 5201 may be some portion of the encapsulant 5200, which is disposed between a side 5120TS of the upper-side second semiconductor die 5120TD and a lateral surface 5200S of the encapsulant 5200. The encapsulant-second sub-portion 5202 may be some portion of the encapsulant 5200, which is disposed between a side 5110S of the first semiconductor die 5110 and the lateral surface 5200S of the encapsulant 5200. The encapsulant-third sub-portion 5203 may be some portion of the encapsulant 5200, which is disposed between a side 5120BS of the lower-side second semiconductor die 5120BD and the lateral surface 5200S of the encapsulant 5200.

As the overhang portion 5110H of the first semiconductor die 5110 protrudes farther into the encapsulant 5200, the volume of the encapsulant-second sub-portion 5202 may be smaller than that of the encapsulant-first sub-portion 5201 or the encapsulant-third sub-portion 5203. Accordingly, a second shrinkage force SF2 that occurs in the encapsulant-second sub-portion 5202 may be smaller than each of first and third shrinkage forces SF1 and SF3 that occur in the encapsulant-first and third sub-portions 5201 and 5203, respectively. As the second shrinkage force SF2 may have a relatively small size, the encapsulant-second sub-portion 5202 can be suppressed from being delaminated from the side 5110S of the first semiconductor die 5110. Accordingly, the encapsulant 5200 can also be suppressed from being delaminated.

The first shrinkage force SF1 which may occur in the encapsulant-first sub-portion 5201 may be propagated in a propagation direction PD that is substantially perpendicular to a direction on which the first shrinkage force SF1 acts. When the first shrinkage force SF1 that occurs in the encapsulant-first sub-portion 5201 is propagated to an interface portion between the encapsulant-third sub-portion 5203 and the side 5120BS of the lower-side second semiconductor die 5120BD, an additional shrinkage force to which the first shrinkage force SF1 has been propagated along with the third shrinkage force SF3 may be added to the interface portion between the encapsulant-third sub-portion 5203 and the side 5120BS of the lower-side second semiconductor die 5120BD.

As the overhang portion 5110H of the first semiconductor die 5110 blocks the interface portion between the encapsulant-third sub-portion 5203 and the side 5120BS of the lower-side second semiconductor die 5120BD, the first shrinkage force SF1 can be blocked from being delivered to the interface portion between the encapsulant-third sub-portion 5203 and the side 5120BS of the lower-side second semiconductor die 5120BD. The overhang portion 5110H of the first semiconductor die 5110 can block the first shrinkage force SF1 and the third shrinkage force SF3 from influencing each other. As described above, the overhang portion 5110H of the first semiconductor die 5110 may induce the shrinkage forces SF1, SF2, and SF3 that are generated by the shrinkage of the encapsulant 5200 to be distributed. As the shrinkage forces SF1, SF2, and SF3 are distributed as described above, the encapsulant 5200 can be suppressed from being delaminated.

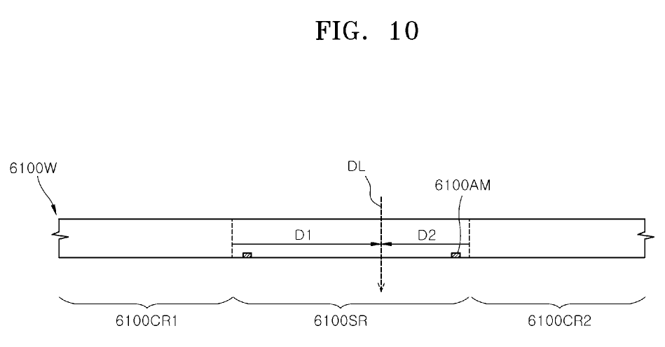

FIGS. 10 and 11 are schematic cross-sectional views illustrating a method of dicing semiconductor dies according to an embodiment.

Referring to FIG. 10, a semiconductor wafer 6100W in which a scribe lane region 6100SR has been disposed between a first chip region 6100CR1 and a second chip region 6100CR2 may be formed. Alignment marks 6100AM may be disposed in the scribe lane region 6100SR. A dicing location DL may be designated within the scribe lane region 6100SR. A location that has been offset from the first chip region 6100CR1 by a first distance D1 may be set as the dicing location DL by using the alignment mark 6100AM as a criterion for setting the location. In the dicing location DL, a first distance D1 that is offset from the first chip region 6100CR1 and a second distance D2 that is offset from the second chip region 6100CR2 may be differently set.

Referring to FIGS. 10 and 11, the semiconductor wafer 6100W may be diced along the dicing location DL. The semiconductor wafer 6100W may be diced through a sawing process using a blade or through a dicing process using a laser. The semiconductor wafer 6100W may be diced into a first semiconductor die 6110 and a second semiconductor die 6120 by the dicing process. The first semiconductor die 6110 may include a first scribe lane region 6100SR1 having a first width W1. The second semiconductor die 6120 may include a second scribe lane region 6100SR2 having a second width W2. The first width W1 and the second width W2 may be different sizes. The first semiconductor die 6110 may be used as the first semiconductor die 3110 in FIG. 7. The second semiconductor die 6120 may be used as the second semiconductor die 3120 in FIG. 7.

The semiconductor dies 6110 and 6120 in which the scribe lane regions 6100SR1 and 6100SR2 have been implemented to have different widths W1 and W2 may be formed by setting the dicing location DL so that the first distance D1 offset from the first chip region 6100CR1 and the second distance D2 offset from the second chip region 6100CR2 are different from each other. Such semiconductor dies 6110 and 6120 may be used to form the die stacks (10 in FIGS. 1, 20 in FIGS. 6, 30 in FIG. 7, and 40 in FIG. 8) that have been presented in the present disclosure.

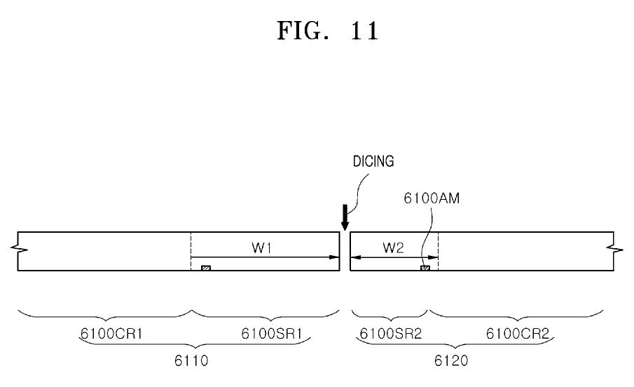

FIG. 12 is a block diagram illustrating an electronic system including a memory card 7800 employing at least one stack package according to an embodiment of the present disclosure. The memory card 7800 includes a memory 7810, such as a nonvolatile memory device, and a memory controller 7820. The memory 7810 and the memory controller 7820 may store data or read out the stored data. At least one of the memory 7810 and the memory controller 7820 may include at least one semiconductor package according to an embodiment of the present disclosure.

The memory 7810 may include a nonvolatile memory device to which the technology of the present disclosure is applied. The memory controller 7820 may control the memory 7810 such that stored data is read out or data is stored in response to a read/write request from a host 7830.

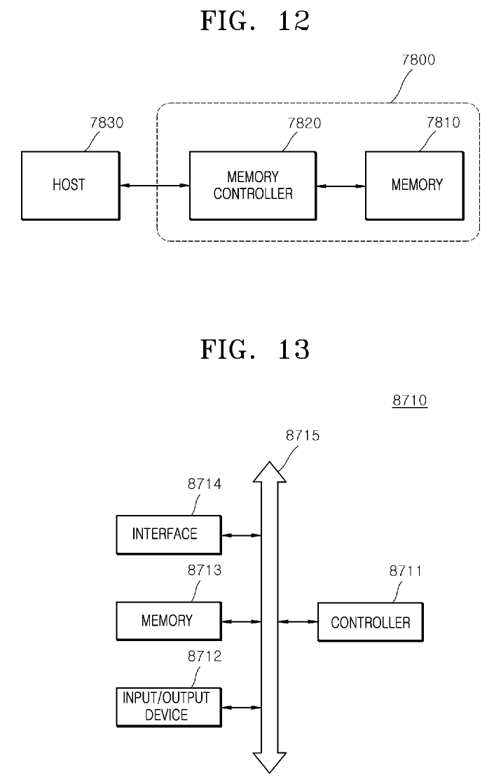

FIG. 13 is a block diagram illustrating an electronic system 8710 including at least one of the stack package according to an embodiment of the present disclosure. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 and/or the memory 8713 may include at least one semiconductor package according to an embodiment of the present disclosure. The input/output device 8712 may include at least one selected among a keypad, a keyboard, a display device, a touch screen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or WiBro (wireless broadband Internet).

The embodiments of the present disclosure have been described so far. A person having ordinary knowledge in the art to which the present teachings pertain will understand that the present teachings may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A stack package comprising:
a die stack in which first semiconductor dies and second semiconductor dies are alternately stacked; and
an encapsulant that covers first and second sides of the die stack, which are opposite to each other,
wherein the encapsulant comprises an encapsulant-first portion that covers the first side of the die stack and an encapsulant-second portion that covers the second side of the die stack,
the first semiconductor dies comprise first overhang portions that protrude farther into the encapsulant-first portion than the second semiconductor dies, and
the second semiconductor dies comprise second overhang portions that protrude farther into the encapsulant-second portion than the first semiconductor dies.

2. The stack package of claim 1, wherein:
a first semiconductor die comprises a first chip region between first and third scribe lane regions of the first semiconductor die,
a second semiconductor die comprises a second chip region between second and fourth scribe lane regions of the second semiconductor die,
the second chip region overlaps the first chip region,
the second scribe lane region overlaps a portion of the first scribe lane region, and the other portion of the first scribe lane region not overlapped by the second scribe lane region represents a first overhang portion that protrudes beyond the second scribe lane region into the encapsulant, and
the third scribe lane region overlaps a portion of the fourth scribe lane region, and the other portion of the fourth scribe lane region not overlapped by the third scribe lane region represents a second overhang portion that protrudes beyond the third scribe lane region into the encapsulant.

3. The stack package of claim 2, wherein:
the first chip region of the first semiconductor die and the second chip region of the second semiconductor die have the same width,
the third scribe lane region of the first semiconductor die has a width smaller than a width of the fourth scribe lane region of the second semiconductor die, and
the second scribe lane region of the second semiconductor die has a width smaller than a width of the first scribe lane region of the first semiconductor die.

4. The stack package of claim 2, wherein the first and second semiconductor dies further comprise alignment marks that indicate locations at which the first and second semiconductor dies are stacked so that the second chip region of the second semiconductor die overlaps the first chip region of the first semiconductor die.

5. The stack package of claim 2, wherein the first and second semiconductor dies further comprise through vias that are disposed in the first and second chip regions.

6. The stack package of claim 2, wherein a second semiconductor die is disposed at a top tier of the die stack and has a greater thickness than each of the first semiconductor dies.

7. The stack package of claim 2, further comprising a base die, wherein:
the alternately stacked first and second semiconductor dies are stacked on the base die, and
the encapsulant fills a gap between the alternately stacked first and second semiconductor dies and the base die and fills gaps between the first and second semiconductor dies.
